(19) United States
(12) Patent Application Publication
(10) Pub. No.: US 2026/0190758 A1
(43) Pub. Date: Jul. 2, 2026

(54) Display Apparatus

(71) Applicant: LG Display Co., Ltd., Seoul (KR)

(72) Inventors: KyungEon Lee, Paju-si, Gyeonggi-do (KR); Sungman Han, Paju-si, Gyeonggi-do (KR)

(21) Appl. No.: 19/334,306

(22) Filed: Sep. 19, 2025

(30) Foreign Application Priority Data
Dec. 30, 2024 (KR) 10-2024-0200819

(51) Int. Cl. H10K 59/80; H10K 102/00

(52) U.S. Cl. CPC H10K 59/80521; H10K 59/878; H10K 2102/3023

(57) ABSTRACT

A display apparatus comprising: a substrate having a plurality of subpixels; a first planarization layer on the substrate; a second planarization layer on the first planarization layer and having a refractive index that is different from a refractive index of the first planarization layer; and a sloped reflective portion on the second planarization layer and inclined with respect to the substrate in a non-light emission area between the plurality of subpixels, the second planarization layer includes an upper sloped portion that partially overlaps the sloped reflective portion and arranged obliquely with respect to the substrate, the first planarization layer includes a lower sloped portion that is closer to the substrate than the upper sloped portion and arranged obliquely with respect to the substrate.

### CROSS-REFERENCE TO RELATED APPLICATION

This application claims the benefit of the Republic of Korea Patent Application No. 10-2024-0200819 filed on Dec. 30, 2024, which is hereby incorporated by reference in its entirety.

### BACKGROUND

### Field of Technology

The present disclosure relates to a display apparatus for displaying an image.

### Discussion of the Related Art

With the advancement of information-oriented society, various requirements for display apparatuses for displaying an image are increasing. Therefore, various display apparatuses such as liquid crystal display apparatuses, plasma display panels, organic light emitting display apparatuses, and quantum-dot light emitting display apparatuses and electroluminescent display apparatuses are being used recently.

In display apparatuses, organic light-emitting display apparatuses are self-emitting display apparatuses and do not require a separate backlight compared to liquid crystal display apparatuses, so they can be made thin and light, and have an advantage of low power consumption.

Recently, organic light emitting display apparatuses of a bottom emission type where reflective electrodes are disposed along grooves after the grooves are formed at boundary portions between subpixels are being developed for increasing the light extraction efficiency of light emitted from an emission layer of each of a plurality of subpixels. Since organic light emitting display apparatuses of the bottom emission type must emit light downward, the reflective electrodes around the light-emission area must be arranged at an angle. However, if an angle of inclination of the reflective electrodes with respect to ground is too small, color mixing between subpixels may occur. Therefore, organic light emitting display apparatuses of the bottom emission type have limitations in improving a viewing angle.

### SUMMARY

An embodiment of the present disclosure is directed to providing a display apparatus whose viewing angle can be improved.

Further, an embodiment of the present disclosure is directed to providing a display apparatus in which the light extraction efficiency of light emitted from a light-emitting element layer can be improved.

Further, an embodiment of the present disclosure is directed to providing a display apparatus in which the overall power consumption can be reduced through light extraction in a non-light emission area.

The problems to be solved by the examples of the present disclosure are not limited to those mentioned above, and other problems not mentioned will be apparent to one of ordinary skill in the art to which the technical spirits of the present disclosure belong from the following description.

In one embodiment, a display apparatus comprises: a substrate having a plurality of subpixels; a first planarization layer on the substrate; a second planarization layer on the first planarization layer, the second planarization layer having a refractive index that is different from a refractive index of the first planarization layer; and a sloped reflective portion on the second planarization layer, the sloped reflective portion inclined with respect to the substrate in a non-light emission area that is between the plurality of subpixels, wherein the second planarization layer includes an upper sloped portion that partially overlaps the sloped reflective portion and is arranged obliquely with respect to the substrate, wherein the first planarization layer includes a lower sloped portion that is closer to the substrate than the upper sloped portion and is arranged obliquely with respect to the substrate.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a schematic plan view of a display apparatus according to one embodiment of the present disclosure.

FIG. 2 is a schematic plan view showing one pixel illustrated in FIG. 1 according to one embodiment of the present disclosure.

FIG. 3 is a schematic cross-sectional view of the line I-I′ shown in FIG. 2 according to one embodiment of the present disclosure.

FIG. 4 is an enlarged view of part F shown in FIG. 3 according to one embodiment of the present disclosure.

FIG. 5 is a schematic cross-sectional view of the line II-II′ shown in FIG. 2 according to one embodiment of the present disclosure.

FIG. 6 is a schematic partial cross-sectional view of a display apparatus according to a second embodiment of the present disclosure.

FIG. 7 is a schematic partial cross-sectional view of a display apparatus according to a third embodiment of the present disclosure.

FIG. 8 is a schematic partial cross-sectional view of a display apparatus according to a fourth embodiment of the present disclosure.

### DETAILED DESCRIPTION

Reference will now be made in detail to the embodiments of the present disclosure, examples of which are illustrated in the accompanying drawings. Wherever possible, the same reference numbers will be used throughout the drawings to refer to the same or like parts. Advantages and features of the present disclosure, and implementation methods thereof will be clarified through following embodiments described with reference to the accompanying drawings.

The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Further, the present disclosure is only defined by scopes of claims.

A shape, a size, a ratio, an angle, and a number disclosed in the drawings for describing embodiments of the present disclosure are merely one example, and thus, the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted.

In a case where ‘comprise’, ‘have’, and ‘include’ described in the present disclosure are used, another part may be added unless ‘only˜’ is used. The terms of a singular form may include plural forms unless referred to the contrary.

In construing an element, the element is construed as including an error range although there is no explicit description.

In describing a position relationship, for example, when a position relation between two parts is described as ‘on˜’, ‘over˜’, ‘under˜’, and ‘next˜’, one or more other parts may be disposed between the two parts unless ‘just’ or ‘direct’ is used.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

“X-axis direction”, “Y-axis direction” and “Z-axis direction” should not be construed by a geometric relation only of a mutual vertical relation and may have broader directionality within the range that elements of the present disclosure may act functionally.

The term “at least one” should be understood as including any and all combinations of one or more of the associated listed items. For example, the meaning of “at least one of a first item, a second item and a third item” denotes the combination of all items proposed from two or more of the first item, the second item and the third item as well as the first item, the second item or the third item.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in co-dependent relationship.

Hereinafter, the embodiments of the present disclosure will be described in detail with reference to the accompanying drawings.

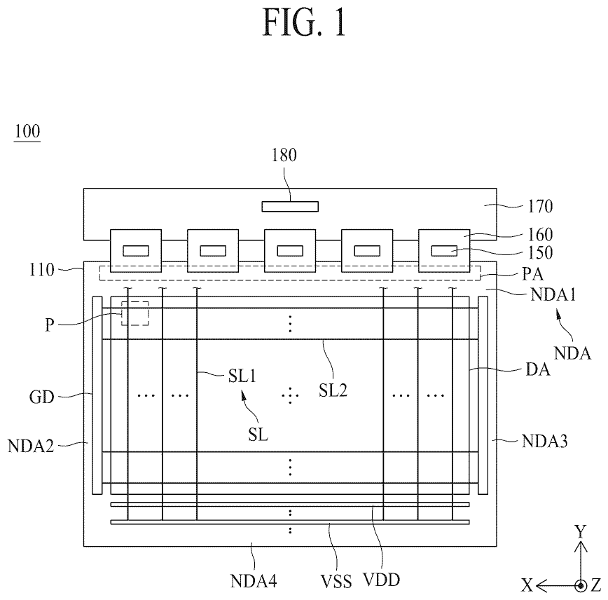

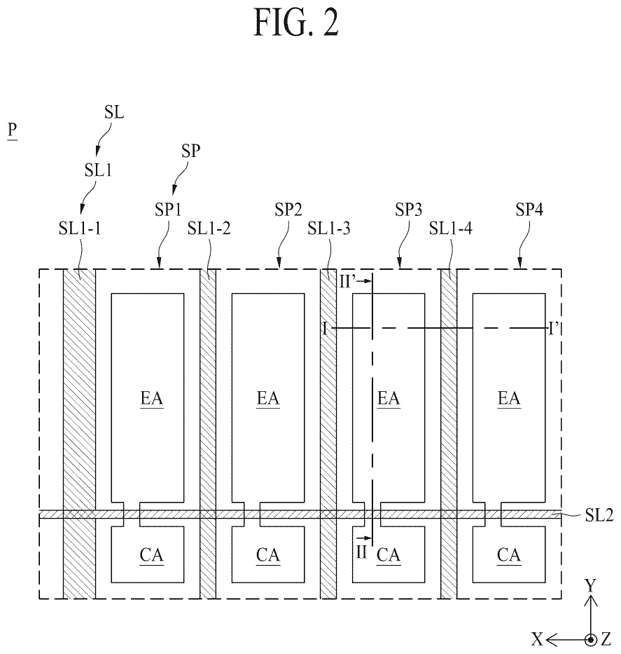

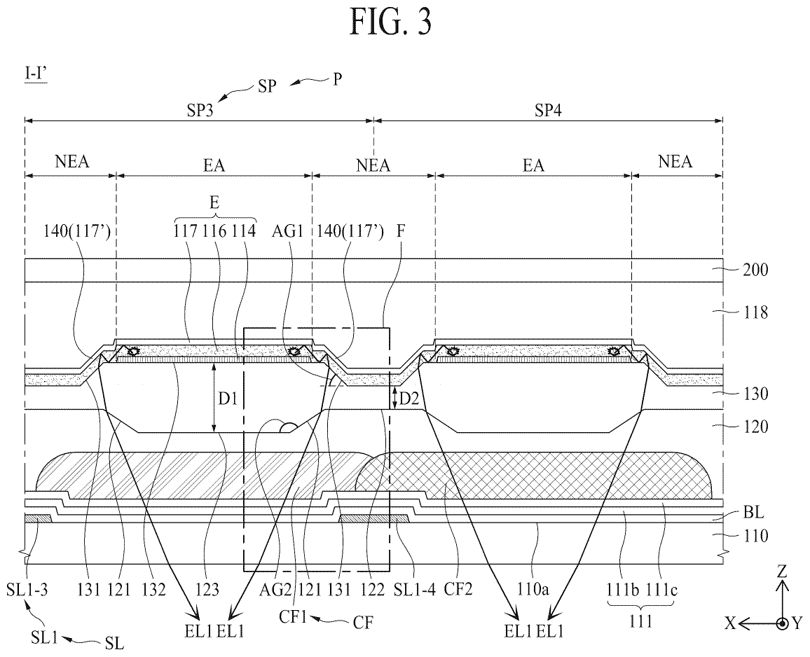

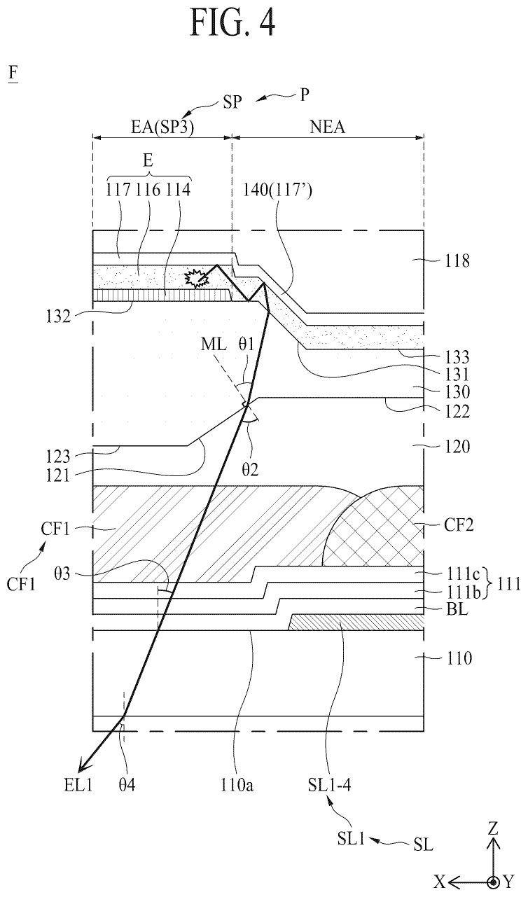

FIG. 1 is a schematic plan view of a display apparatus according to one embodiment of the present disclosure, FIG. 2 is a schematic plan view showing one pixel illustrated in FIG. 1 according to one embodiment of the present disclosure, FIG. 3 is a schematic cross-sectional view of the line I-I′ shown in FIG. 2 according to one embodiment of the present disclosure, and FIG. 4 is an enlarged view of part F shown in FIG. 3 according to one embodiment of the present disclosure.

Hereinafter, a first direction (Y-axis direction) represents a vertical direction based on FIG. 1, a second direction (X-axis direction) represents a horizontal direction based on FIG. 1, and a third direction (Z-axis direction) represents a thickness direction of a display apparatus 100. The first direction (Y-axis direction) may be a direction parallel to a first line SL1 (e.g., data line). The second direction (X-axis direction) may be a direction parallel to a second line SL2 (e.g., gate line).

The following description will be based on that the display apparatus 100 according to one embodiment of the present disclosure is an organic light emitting display apparatus, but is not limited thereto. That is, the display apparatus according to one embodiment of the present disclosure may be implemented as any one of a liquid crystal display apparatus, a field emission display apparatus, a quantum dot lighting emitting diode apparatus, and an electrophoretic display apparatus as well as the organic light emitting display apparatus.

Referring to FIG. 1, a display apparatus 100 according to one embodiment of the present disclosure may include a display panel having a gate driver GD. The display panel may include a substrate 110 and an opposing substrate 200 (shown in FIG. 3) bonded to each other.

The substrate 110 according to one example may include a display area DA in which a plurality of pixels P having a plurality of subpixels SP are arranged, and a non-display area NDA around the display area DA. The substrate 110 may further include lines SL arranged between the plurality of pixels P (or the plurality of sub-pixels SP).

Referring to FIG. 1, the display apparatus 100 according to one embodiment of the present disclosure may include a source drive integrated circuit (hereinafter referred to as “IC”) 150, a flexible film 160, a circuit board 170, and a timing control portion 180 (e.g., a circuit).

The substrate 110 may include a thin film transistor, and may be a transistor array substrate, a lower substrate, a base substrate, or a first substrate. The substrate 110 may be a transparent glass substrate or a transparent plastic substrate.

The opposing substrate 200 may be bonded to the substrate 110 via an adhesive member. For example, the opposing substrate 200 has a smaller size than the substrate 110 and can be bonded to a remaining portion except for a pad portion of the substrate 110. The opposing substrate 200 may be an upper substrate, a second substrate, or an encapsulation substrate.

The gate driver GD supplies gate signals to the gate lines in accordance with the gate control signal input from the timing control portion 180. When the source drive IC 150 is manufactured as a driving chip, the source drive IC 150 may be packaged in the flexible film 160 in a chip on film (COF) method or a chip on plastic (COP) method.

Pads, such as data pads, may be formed in the non-display area of the display panel. Lines connecting the pads with the source drive IC 150 and lines connecting the pads with lines of the circuit board 170 may be formed in the flexible film 160. The flexible film 160 may be attached onto the pads by using an anisotropic conducting film, whereby the pads may be connected with the lines of the flexible film 160.

Referring to FIG. 1, the display area DA is an area where an image is displayed, and may be a pixel array area, an active area, a pixel array unit, a display unit, or a screen. For example, the display area DA may be disposed at a central portion of the display panel.

The display area DA according to one example may include gate lines, data lines, pixel power lines, and a plurality of pixels P. Each of the plurality of pixels P may include a plurality of sub-pixels SP that may be defined by gate lines and data lines. Each of the plurality of subpixels SP may include a light-emission area EA and a circuit area CA adjacent to the light-emission area EA.

The light-emission area EA according to one example may be defined as the smallest unit area where actual light is emitted. The circuit area CA according to one example may be defined as an area in which a thin film transistor for driving the emission of light is provided in the light-emission area EA. As illustrated in FIG. 2, the circuit area CA may be arranged adjacent to one side of the light-emission area EA. For example, the light-emission area EA and the circuit area CA may be arranged in the first direction (Y-axis direction) so as to be arranged parallel to a first line SL1. For example, the first line SL1 may be any one of a pixel power line, a common power line, a reference line, and a data line.

Meanwhile, at least four subpixels SP arranged adjacently and configured to emit different colors among a plurality of subpixels SP constitute one pixel P (or unit pixel P). The one pixel P may include, but is not limited to, a red subpixel, a green subpixel, a blue subpixel, and a white subpixel. For example, the red subpixel may be a first subpixel SP1, the white subpixel may be a second subpixel SP2, the blue subpixel may be a third subpixel SP3, and the green subpixel may be a fourth subpixel SP4.

Each of the plurality of subpixels SP may include a thin film transistor and an organic light-emitting element connected to the thin film transistor. The subpixel may include a light-emitting layer (or organic light-emitting layer) interposed between an anode electrode and a reflective portion.

The light-emitting layer (or organic light-emitting layer) arranged in each of the plurality of subpixels SP can individually emit different color light or commonly emit white light. For example, when the light-emitting layer (or organic light-emitting layer) of each of the plurality of sub-pixels SP commonly emits white light, each of the red sub-pixel, the green sub-pixel, and the blue sub-pixel may include a color filter CF (or wavelength conversion member CF) that converts the white light into light of a different color. In this case, the white subpixel according to one example may not have a color filter. In a display apparatus 100 according to one embodiment of the present disclosure, an area provided with a red color filter (not shown) may be a red subpixel SP1, an area provided with a blue color filter CF1 (shown in FIG. 3) may be a blue subpixel SP3, an area provided with a green color filter CF2 may be a green subpixel SP4, and an area without the color filter may be a white subpixel SP4.

Each of the subpixels SP supplies a predetermined current to the organic light emitting element in accordance with a data voltage of the data line when a gate signal is input from the gate line by using the thin film transistor. For this reason, the light emitting layer of each of the subpixels may emit light with a predetermined brightness in accordance with the predetermined current.

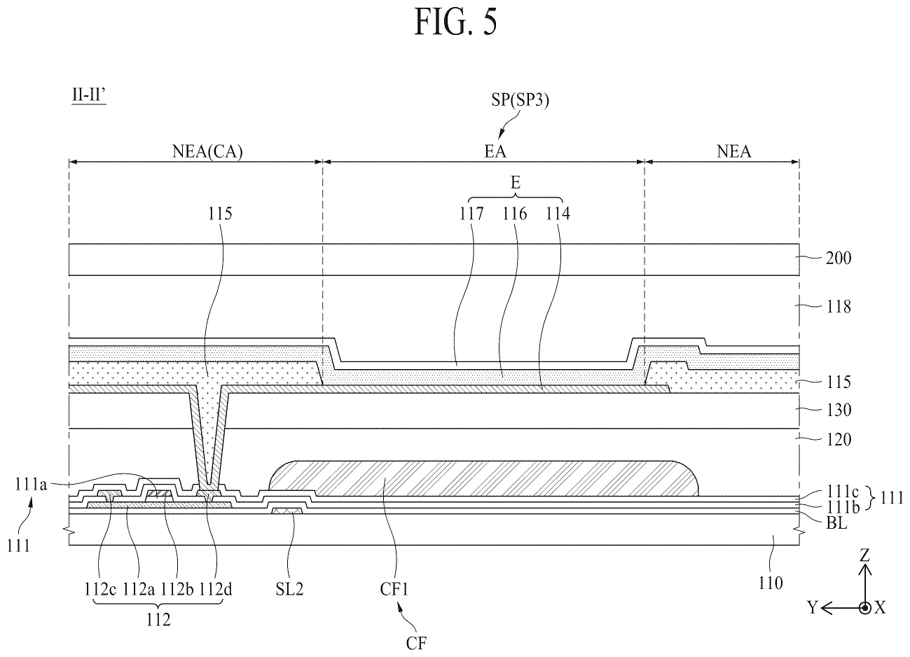

Meanwhile, each of the plurality of subpixels SP emitting different colors has the same shape and size as in FIG. 2 and is arranged with four subpixels spaced apart from each other. For example, it may include a first subpixel SP1, a second subpixel SP2, a third subpixel SP3, and a fourth subpixel SP4. However, it is not necessarily limited thereto, and at least one of the first to fourth subpixels SP1, SP2, SP3, SP4 may have a different shape and/or size. A description of a structure of each of the subpixels SP will be described below with reference to FIG. 5.

The display area DA may include a plurality of sub-pixels SP, as illustrated in FIG. 2, and each of the plurality of sub-pixels SP may include a light-emission area EA and a circuit area CA. In addition, as shown in FIG. 1, the display area DA may include a first line SL1 adjacent to each of the plurality of sub-pixels SP, and a second line SL2 arranged in a different direction from the first line SL1, for example, in the second direction (X-axis direction). The first line SL1 can be arranged in the first direction (Y-axis direction) as shown in FIG. 2. The first line SL1 and the second line SL2 according to one example are for receiving power and/or image signals from at least one of the gate driver GD and the pad portion PA and transmitting them to the plurality of sub-pixels SP of the display area DA. According to one example, the second line SL2 can be connected to a pixel power shorting bar VDD and/or a common power shorting bar VSS in the fourth non-display area NDA4.

The first line SL1 may include a plurality of first sub-lines SL1-1, SL1-2, SL1-3, SL1-4. Each of the plurality of first sub-lines SL1-1, SL1-2, SL1-3, SL1-4 may be any one of a pixel power line, a common power line, a reference line, and a data line. The plurality of first sub-lines SL1-1, SL1-2, SL1-3, SL1-4 may mean a group of signal lines connected to one sub-pixel SP.

The second line SL2 may be electrically connected to at least one of the plurality of first sub-lines and may be connected to each of the sub-pixels SP. Accordingly, each of the plurality of sub-pixels SP may receive power and/or image signals through the first line SL1 and the second line SL2 to output an integrated image. According to one example, a plurality of second lines SL2 may be provided. In this case, the second line SL2 may include a plurality of sub-lines connected to the first line SL1 and a gate line connected to a gate driver GD.

The non-display area NDA is an area on which an image is not displayed, and may be a peripheral circuit area, a signal supply area, an inactive area or a bezel area. The non-display area NDA may be configured to be in the vicinity of the display area DA. That is, the non-display area NDA may be disposed to surround the display area DA. That is, the non-display area NDA can be arranged to surround the display area DA.

The display apparatus 100 according to one embodiment of the present disclosure may have a pad portion PA placed in the non-display area NDA. The pad portion PA may supply power and/or a signal for the pixel P provided in the display area DA to output an image. The non-display area NDA can include a first non-display area NDA1, a second non-display area NDA2, a third non-display area NDA3, and a fourth non-display area NDA4.

According to one example, the pad portion PA may be placed in the first non-display area NDA1 located above the display area DA based on FIG. 1.

The gate driver GD supplies gate signals to the gate lines in accordance with the gate control signal input from the timing control portion 180. The gate driver GD may be formed on one side of the display area DA of the display panel or on the non-display area NDA outside both sides of the display area DA in a gate driver in panel GIP method as shown in FIG. 1.

The plurality of gate drivers GD may be separately disposed on a left side of the display area DA, that is, the second non-display area NDA2 and a right side of the display area DA, that is, the third non-display area NDA3.

The pixel power shorting bar VDD and the common power shorting bar VSS can be placed in the fourth non-display area NDA4 facing the pad portion PA based on the display area DA.

Referring to FIG. 3, the display area DA (or each of the plurality of sub-pixels SP) may include the light-emission area EA and the non-light emission area NEA. The light-emission area EA may be provided adjacent to the non-light emission area NEA.

The light emission area EA is the area where light is emitted by the organic light-emitting element layer E (e.g., an organic light-emitting device, an organic light-emitting element, or organic light-emitting diode). The light emission area EA may correspond to an area in the pixel P that emits light. The non-light emission area NEA is the area that does not transmit most of the light incident from the outside.

For example, the non-light emission area NEA may be an area excluding the light emission area EA where light is emitted. In one example, the non-light emission area NEA may include a circuit area CA (shown in FIG. 5). The circuit area CA may include a thin film transistor 112 for driving each of the plurality of subpixels SP (or an organic light emitting element layer E of each of the plurality of subpixels SP).

The non-light emission area NEA may refer to an area that is provided in the display area DA and does not emit light, and may be expressed as a dead zone because it does not emit light. The dead zone according to one example may be an area in which a black matrix and/or a bank is provided, but is not limited thereto, and may refer to an area in which light is not emitted.

Referring to FIG. 3, the display apparatus 100 according to one embodiment of the present disclosure may include a substrate 110, a first planarization layer 120, a second planarization layer 130, and a sloped reflective portion 140.

The first planarization layer 120 may be disposed on the substrate 110. The second planarization layer 130 may be disposed on the first planarization layer 120. According to one example, the second planarization layer 130 may have a refractive index that is different from a refractive index of the first planarization layer 120. For example, the second planarization layer 130 may have a refractive index that is higher than the refractive index of the first planarization layer 120. This is to refract light at an interface (or boundary surface) between the first planarization layer 120 and the second planarization layer 130.

The sloped reflective portion 140 reflects light emitted from the organic light-emitting layer 116 toward an adjacent subpixel and toward the substrate 110. For example, the sloped reflective portion 140 reflects light emitted from the organic light-emitting layer 116 and wave-guided between an interface between the organic light-emitting layer 116 and the second planarization layer 130 (or an interface between the pixel electrode 114 (e.g., a first electrode) and the second planarization layer 130) and the reflective electrode 117 (e.g., a second electrode) (or an upper surface of the pixel electrode 114) toward the substrate 110. According to one example, the sloped reflective portion 140 may be placed in the non-light emission area NEA (or the first non-light emission area NEA1) between the plurality of subpixels SP. As shown in FIG. 3, the sloped reflective portion 140 may be placed on the second planarization layer 120. Since the sloped reflective portion 140 is a part of the reflective electrode 117 positioned in the non-light emission area NEA (or the first non-light emission area NEA1), it may be indicated by the drawing symbol 117′. As shown in FIG. 3, the sloped reflective portion 140 is non-overlapping with the pixel electrode 114.

Meanwhile, in the display apparatus 100 according to one embodiment of the present disclosure, the second planarization layer 130 may include an upper sloped portion 131 that is arranged obliquely and partially overlaps the sloped reflective portion 140. According to one example, the upper sloped portion 131 can be formed by depositing a material forming the second planarization layer 130 on the entire surface of the substrate 110 so as to cover the first planarization layer 120, and then partially removing the second planarization layer 130 between the plurality of subpixels SP by a patterning process (or an ashing process). Accordingly, the substrate 110 may include a pattern portion (or upper pattern portion) formed concavely in the non-light emission area NEA between the plurality of subpixels SP in a direction toward the substrate 110. The upper sloped portion 131 may be an inclined surface of the pattern portion (or upper pattern portion) formed concavely. Thus, the second planarization layer 130 has a concave portion in a direction of the substrate 110 that is disposed in the non-light emission area NEA. As described above, since the upper pattern portion is formed in the non-light emission area NEA, the upper sloped portion 131 may not overlap (e.g., non-overlapping) with the light emission area EA.

A width of the pattern portion (upper pattern portion) according to one example may be provided to become narrower in the direction from the opposing substrate 200 toward the substrate 110. Accordingly, the upper sloped portion 131 may be arranged to be inclined between the organic light-emitting layer 116 and the second planarization layer 130 (or the first planarization layer 120). For example, as shown in FIG. 3, the upper sloped portion 131 may be arranged in the non-light emission area NEA and may be arranged to be inclined in a direction toward the light emission area EA (or pixel electrode 114) as it goes upward (or in a direction from the substrate 110 toward the opposing substrate 200. As shown in FIG. 3, the upper sloped portion 131 may mean an inclined boundary surface (or inclined surface) between the second planarization layer 130 and the organic light-emitting layer 116.

Referring to FIG. 3, the first planarization layer 120 may include a lower sloped portion 121 that is arranged closer to the substrate 110 than the upper sloped portion 131 and is arranged at an inclined angle with respect to the substrate 110. According to one example, the lower sloped portion 121 may be formed by partially removing the first planarization layer 120 by a pattern process (or an ashing process) after the material forming the first planarization layer 120 is completely deposited on the substrate 110 to cover the color filter CF. For example, the lower sloped portion 121 may be formed by partially removing the first planarization layer 120 that partially overlaps the light-emission area EA. Accordingly, the first planarization layer 120 may include a pattern portion (or lower pattern portion) that is formed concavely in a direction toward the substrate 110 and partially overlaps the light-emission area EA of each of the plurality of subpixels SP. Thus, the first planarization layer 120 has a concave portion in a direction of the substrate 110 that is disposed in the light emission area EA. In one embodiment, the lower sloped portion 121 includes a first portion that is in the light-emission area EA and a second portion that is in the non-light emission area NEA. The lower sloped portion 121 may be an inclined surface of the pattern portion (or lower pattern portion) that is formed concavely.

A width of the pattern portion (or lower pattern portion) according to one example may be provided to become narrower in the direction from the opposing substrate 200 toward the substrate 110. Accordingly, the lower sloped portion 121 may be arranged to be inclined between the color filter CF and the second planarization layer 130. For example, as shown in FIG. 3, the lower sloped portion 121 may be arranged to partially overlap the light-emission area EA and to be inclined in the direction toward the non-light emission area NEA (or the light-emission area EA of the adjacent subpixel SP) as it goes upward (or in the direction from the substrate 110 toward the opposing substrate 200). As shown in FIG. 3, the lower sloped portion 121 may mean an inclined boundary surface (or inclined surface) between the second planarization layer 130 and the first planarization layer 120.

Therefore, the display apparatus 100 according to one embodiment of the present disclosure may be arranged such that the upper sloped portion 131 and the lower sloped portion 121 are inclined in different directions. For example, as shown in FIG. 3, the upper sloped portion 131 may be arranged at an acute angle AG1 with respect to an upper surface 110a of the substrate 110. And, the lower sloped portion 121 may be arranged at an obtuse angle AG2 that is greater than the acute angle AG1 with respect to the upper surface 110a of the substrate 110.

In the display apparatus 100 according to one embodiment of the present disclosure, each of the upper sloped portion 131 and the lower sloped portion 121 can refract light reflected by the sloped reflective portion 140 among light emitted from the light emission area EA. Since the upper sloped portion 131 is a boundary surface between the organic light emitting layer 116 and the second planarization layer 130, light can be refracted by the difference in refractive index between the organic light emitting layer 116 and the second planarization layer 130. Since the lower sloped portion 121 is the boundary surface between the second planarization layer 130 and the first planarization layer 120, it can refract light due to the difference in refractive index between the second planarization layer 130 and the first planarization layer 120. Therefore, as shown in FIG. 3, the upper sloped portion 131 can primarily refract light that is reflected by the slope reflection portion 140 among the light emitted from the light-emission area EA and is incident on the upper sloped portion 131. In addition, the lower sloped portion 121 can secondarily refract light that is first refracted by the upper sloped portion 131 and is incident on the lower sloped portion 121.

As described above, in the display apparatus 100 according to one embodiment of the present disclosure, the upper sloped portion 131 and the lower sloped portion 121 are arranged to be inclined in different directions, so that light reflected by the sloped reflective portion 140 in the non-light emission area NEA can be refracted toward the light emission area EA of the emitting subpixel SP. For example, as shown in FIG. 3, light reflected by the sloped reflective portion 140 may be refracted by each of the upper sloped portion 131 and the lower sloped portion 121, and may be emitted toward a center of the light-emission area EA rather than in a front direction (e.g., a vertical direction with respect to the upper surface 110a of the substrate 110). Therefore, the display apparatus 100 according to one embodiment of the present disclosure can change the light path of light reflected by the sloped reflective portion 140 and emitted to the substrate 110 to be directed toward the center portion of the light-emission area EA rather than the front direction, thereby improving the viewing angle. An improved viewing angle may mean that luminance in the viewing angle direction is improved. Hereinafter, a refracted light emitted from the display apparatus 100 according to one embodiment of the present disclosure is defined as first refracted light EL1.

As a result, the display apparatus 100 according to one embodiment of the present disclosure can improve the viewing angle because the light reflected by the sloped reflective portion 140 can be refracted in a direction (for example, a direction toward a light emission area EA of an emitting subpixel SP) (or the inward direction) other than the front direction (e.g., the vertical direction with respect to the upper surface 110a of the substrate 110) by the upper sloped portion 131 and the lower sloped portion 121.

A general bottom-emission display apparatus can emit light emitted from a light-emitting layer downward by using reflective electrodes arranged at an angle. However, if an angle of inclination of the reflective electrodes with respect to ground is too small, color mixing between subpixels may occur. Therefore, the general bottom-emission display apparatus has limitations in improving viewing angle of the display apparatus.

In contrast, a display apparatus 100 according to one embodiment of the present disclosure is provided to include an upper sloped portion 131 partially overlapping the sloped reflective portion 140, and a lower sloped portion 121 positioned closer to the substrate 110 than the upper sloped portion 131, so that light can be refracted through the upper sloped portion 131 and the lower sloped portion 121 even without adjusting an inclination angle of the sloped reflective portion 140, so that color mixing can be prevented and a viewing angle can be improved.

In addition, the display apparatus 100 according to one embodiment of the present disclosure is provided with the sloped reflective portion 140 that is inclinedly positioned in the non-light emission area NEA, so that light directed toward an adjacent subpixel can be reflected by the sloped reflective portion 140 and emitted to an outside of the substrate 110, thereby improving light extraction efficiency.

In addition, since the display apparatus 100 according to one embodiment of the present disclosure can achieve light extraction by the sloped reflective portion 140, the display apparatus can have the same light emission efficiency or can have improved light emission efficiency even at lower power compared to a display apparatus without the sloped reflective portion, so that the overall power consumption can be reduced.

Hereinafter, the structure of each of the plurality of subpixels SP will be specifically described with reference to FIG. 5.

FIG. 5 is a schematic cross-sectional view of the line II-II′ shown in FIG. 2 according to one embodiment.

Referring to FIG. 5, the display apparatus 100 according to one embodiment of the present disclosure can include a buffer layer BL, a plurality of inorganic films 111, a thin film transistor 112, a color filter CF, a first planarization layer 120, a second planarization layer 130, a pixel electrode 114, a bank 115, an organic light emitting layer 116, a reflective electrode 117, and an encapsulation layer 118.

Each of the subpixels SP according to one embodiment may include the plurality of inorganic films 111 provided on an upper surface of the buffer layer BL, including a gate insulating layer 111a, an interlayer insulating layer 111b, and a passivation layer 111c.

Also, each of the subpixels SP may include a color filter CF provided on the plurality of inorganic films 111, a first planarization layer 120 and a second planarization layer 130 provided on the color filter CF. The second planarization layer 130 may be placed on the first planarization layer 120. The pixel electrode 114 may be placed on the second planarization layer 130.

Each of the subpixels SP may further include a bank 115 covering one edge of the pixel electrode 114, an organic light-emitting layer 116 on the pixel electrode 114 and the bank 115, and a reflective electrode 117 on the organic light-emitting layer 116. The encapsulation layer 118 may be placed on the reflective electrode 117.

The thin film transistor 112 for driving of subpixel SP may be arranged on the plurality of inorganic films 111. The plurality of inorganic films 111 may also be expressed in terms of a circuit element layer.

The buffer layer BL may be included in the plurality of inorganic films 111 together with the gate insulating layer 111a, the interlayer insulating layer 111b, and the passivation layer 111c. The pixel electrode 114, the organic light emitting layer 116 and the reflective electrode 117 may be included in a light emitting element layer E.

The buffer layer BL may be formed between the substrate 110 and the gate insulating layer 111a to protect the thin film transistor 112 112. The buffer layer BL may be disposed on the entire surface (or front surface) of the substrate 110. The buffer layer BL may serve to block diffusion of a material contained in the substrate 110 into a transistor layer during a high temperature process of a manufacturing process of the thin film transistor 112.

The thin film transistor 112 (or a drive transistor) according to one example may include an active layer 112a, a gate electrode 112b, a source electrode 112c, and a drain electrode 112d.

The active layer 112a may include a channel area, a drain area and a source area, which are formed in a thin film transistor area of a circuit area CA of the subpixel SP. The drain area and the source area may be spaced apart from each other with the channel area interposed therebetween.

The active layer 112a may be formed of a semiconductor material based on any one of amorphous silicon, polycrystalline silicon, oxide and organic material.

The gate insulating layer 111a may be formed on the channel area of the active layer 112a. As one example, the gate insulating layer 111a may be formed in an island shape only on the channel area of the active layer 112a or may be formed on the entire front surface of the substrate 110 or buffer layer BL including the active layer 112a.

The gate electrode 112b may be formed on the gate insulating layer 111a to overlap the channel area of the active layer 112a.

The interlayer insulating layer 111b can be formed to partially overlap the gate electrode 112b and the drain area and source area of the active layer 112a. The interlayer insulating layer 111b may be formed over the entire light emission area where light is emitted, as in FIG. 3, in the circuit area CA and the subpixel SP.

The source electrode 112c may be electrically connected to the source area of the active layer 112a through a source contact hole provided in the interlayer insulating layer overlapped with the source area of the active layer 112a.

The drain electrode 112d may be electrically connected to the drain area of the active layer 112a through a drain contact hole provided in the interlayer insulating layer overlapped with the drain area of the active layer 112a.

The drain electrode 112d and the source electrode 112c may be made of the same metal material. For example, each of the drain electrode 112d and the source electrode 112c may be made of a single metal layer, a single layer of an alloy or a multi-layer of two or more layers, which is the same as or different from that of the gate electrode 112b.

Additionally, the thin film transistor provided in the pixel area may have a characteristic in which the threshold voltage is shifted by light. To prevent this, the display panel or the substrate 110 may further include a light-shielding layer (not shown) provided under the active layer 112a of at least one of the thin film transistor 112, a first switching thin film transistor, and a second switching thin film transistor.

The light-shielding layer is provided between the substrate 110 and the active layer 112a to block light incident on the active layer 112a through the substrate 110, thereby minimizing changes in the threshold voltage of the transistor caused by external light. In addition, the light shielding layer may be provided between the substrate 110 and the active layer 112a to prevent the thin film transistor from being visible to the user.

The passivation layer 111c may be provided on the substrate 110 to cover the pixel area. The passivation layer 111c covers a drain electrode 112d, a source electrode 112c and a gate electrode 112b of the thin film transistor 112, and the buffer layer BL.

The color filter CF may be placed on the passivation layer 111c. For example, the color filter CF may be placed between the plurality of inorganic films 111 and the first planarization layer 120. The color filter CF may include a red color filter (not shown) arranged in the red subpixel SP1, a blue color filter CF1 arranged in the blue subpixel SP3, and a green color filter CF2 arranged in the green subpixel SP4. Since the white subpixel SP4 is provided to emit white light, it may not include the color filter.

The first planarization layer 120 may be provided on the substrate 110 to cover the passivation layer 111c and the color filter CF. According to one example, the first planarization layer 120 may be placed between the substrate 110 and the pixel electrode 114. The first planarization layer 120 may be formed in the entire circuit area CA in which the thin film transistor 112 is disposed and the entire light emission area EA. In addition, the first planarization layer 120 may be formed in the other non-display area NDA except a pad area PA of the non-display area NDA and the entire display area DA. For example, the first planarization layer 120 may include an extension portion (or an enlarged portion) extended or enlarged from the display area DA to the other non-display area NDA except the pad area PA. Therefore, the first planarization layer 120 may have a size relatively wider than that of the display area DA.

The first planarization layer 120 according to one example may be formed to have a relatively thick thickness, thereby providing a flat surface on the display area DA and the non-display area NDA. For example, the first planarization layer 120 may be made of an organic material such as photo acryl, benzocyclobutene, polyimide and fluorine resin.

The second planarization layer 130 may be disposed on the substrate 110. For example, the second planarization layer 130 may be disposed on the first planarization layer 120. According to one example, the second planarization layer 130 may be disposed between the first planarization layer 120 and the pixel electrode 114. The second planarization layer 130 may be provided to have a different refractive index than the first planarization layer 120, but is not limited thereto. In cases where light efficiency in a front direction is required rather than a viewing angle, the second planarization layer 130 may be provided to have the same refractive index as the first planarization layer 120.

Referring to FIG. 5, an upper surface of the second planarization layer 130 can be provided flat. Accordingly, the pixel electrode 114 on the second planarization layer 130 can also be provided flat, and the organic light-emitting layer 116 and the reflective electrode 117 formed thereon can also be provided in a flat form.

Since the pixel electrode 114, the organic light-emitting layer 116, and the reflective electrode 117, i.e., the organic light-emitting element layer E, are provided flatly in the light-emission area EA, a thicknesses of the pixel electrode 114, the organic light-emitting layer 116, and the reflective electrode 117 can be formed uniformly within the light-emission area EA. Accordingly, the organic light-emitting layer 116 can emit light uniformly without deviation within the light-emission area EA.

The pixel electrode 114 may be formed on the second planarization layer 130. As shown in FIG. 5, the pixel electrode 114 can be connected to a drain electrode or source electrode of the thin film transistor through a contact hole penetrating the second planarization layer 130, the first planarization layer 120, and the passivation layer 111c. An edge portions on both sides of the pixel electrode 114 may be covered by the bank 115. Since FIG. 5 is a cross-sectional view in the first direction (Y-axis direction), the bank 115 may be provided to cover each of an upper edge and a lower edge of the pixel electrode 114 based on a plane (e.g., FIG. 2). In contrast, as shown in FIG. 3, the bank 115 may not be arranged between the plurality of sub-pixels SP adjacent in the second direction (X-axis direction). Accordingly, the display apparatus 100 according to one embodiment of the present disclosure may be provided with a bank-less structure in which the bank 115 is not arranged between the plurality of sub-pixels SP in the second direction (X-axis direction). For example, the plurality of subpixels SP adjacent in the second direction (X-axis direction) may mean two subpixels SP (e.g., a blue subpixel SP3 and a green subpixel SP4) that are equipped to emit different colors.

The pixel electrode 114 may be made of at least one of a transparent metal material or a semi-transmissive metal material.

Because the display apparatus 100 according to an embodiment of the present disclosure is configured as the bottom emission type, the pixel electrode 114 may be formed of a transparent conductive material (or TCO), such as indium tin oxide (ITO) or indium zinc oxide (IZO) capable of transmitting light, or a semi-transmissive conductive material such as magnesium (Mg), silver (Ag), or an alloy of Mg and Ag.

Meanwhile, the material constituting the pixel electrode 114 may include MoTi. The pixel electrode 114 may be a first electrode or an anode electrode.

The bank 115 may be an area, which does not emit light, and can be placed adjacent to the light emission area EA of each of the plurality of sub-pixels SP. For example, the bank 115 may be disposed in the non-light emission area NEA (or non-light emission area NEA on the upper and lower sides of the pixel electrode 114). The bank 115 may be formed to cover a portion where the edge of the pixel electrode 114. Accordingly, the bank 115 may prevent the pixel electrode 114 and the reflective electrode 117 in the edge of the pixel electrode 114. The exposed portion of the pixel electrode 114 that is not covered by the bank 115 may be included in the light emitting portion (or light emission area EA).

After the bank 115 is formed, an organic light emitting layer 116 may be formed to cover the pixel electrode 114 and the bank 115. Thus, the bank 115 may be partially provided between the pixel electrode 114 and the organic light emitting layer 116. The bank 115 can be expressed in terms of a pixel definition films. The bank 115 according to one example may comprise organic material and/or inorganic material.

The organic light emitting layer 116 may be formed on the pixel electrode 114 and the bank 115. The organic light emitting layer 116 can be placed under the reflective electrode 117. According to one example, the organic light emitting layer 116 may be disposed in the light emission area EA and the non-light emission area NEA. The organic light emitting layer 116 may be provided between the pixel electrode 114 and the reflective electrode 117. Thus, when a voltage is applied to each of the pixel electrode 114 and the reflective electrode 117, an electric field is formed between the pixel electrode 114 and the reflective electrode 117. Therefore, the organic light emitting layer 116 may emit light. The organic light emitting layer 116 may be formed of a plurality of subpixels SP and a common layer provided on the bank 115.

The organic light emitting layer 116 according to one embodiment may be provided to emit white light. The organic light emitting layer 116 may include a plurality of stacks which emit lights of different colors. For example, the organic light emitting layer 116 may include a first stack, a second stack, and a charge generating layer (CGL) provided between the first stack and the second stack. The light emitting layer may be provided to emit the white light, and thus, each of the plurality of subpixels SP may include a color filter CF suitable for a corresponding color.

The first stack may be provided on the pixel electrode 114 and may be implemented a structure where a hole injection layer (HIL), a hole transport layer (HTL), an emission layer (EML (B)), and an electron transport layer (ETL) are sequentially stacked.

The charge generating layer may supply an electric charge to the first stack and the second stack. The charge generating layer may include an N-type charge generating layer for supplying an electron to the first stack and a P-type charge generating layer for supplying a hole to the second stack. The N-type charge generating layer may include a metal material as a dopant.

The second stack may be provided on the first stack and may be implemented in a structure where a hole transport layer (HTL), a yellow-green (YG) emission layer (EML(YG)), and an electron injection layer (EIL) are sequentially stacked.

In the display apparatus 100 according to an embodiment of the present disclosure, because the organic light emitting layer 116 is provided as a common layer, the first stack, the charge generating layer, and the second stack may be arranged all over the plurality of subpixels SP. The organic light emitting layer 116, according to another example, may be provided in a three-stacked structure or a four-stacked structure, depending on the number of stacks stacked.

That is, in the display apparatus 100 according to one embodiment of the present disclosure, the organic light-emitting layer 116 (or organic light-emitting element layer E) may be formed in a tandem structure.

The reflective electrode 117 may be formed on the organic light-emitting layer 116. The reflective electrode 117 may be arranged in the non-display area NDA (or a part of the non-display area NDA) and the display area DA. In the display area DA, the reflective electrode 117 may be arranged in the light-emission area EA and the non-light emission area NEA. That is, the reflective electrode 117 may be provided to cover the entire display area DA. As a result, the reflective electrode 117 may be provided to have a size larger than the display area DA and smaller than the substrate 110, so that it may be arranged in the non-display area NDA (or the part of the non-display area NDA) and the display area DA.

The reflective electrode 117 according to one example may include a metal material. The reflective electrode 117 may reflect light emitted from the organic light-emitting layer 116 in the plurality of subpixels SP toward the lower surface of the substrate 110. Therefore, the display apparatus 100 according to an embodiment of the present disclosure may be implemented as a bottom emission display apparatus.

The display apparatus 100 according to one embodiment of the present disclosure is a bottom emission type and has to reflect light emitted from the light emitting layer 116 toward the substrate 110, and thus the reflective electrode 117 may be made of a metal material having high reflectance. According to one example, the reflective electrode 117 may be formed of a metal material having high reflectance such as a silver (Ag), an aluminum (Al), a stacked structure (Ti/Al/Ti) of aluminum and titanium, a stacked structure (ITO/Al/ITO) of aluminum and ITO, an Ag alloy and a stacked structure (ITO/Ag alloy/ITO) of Ag alloy and ITO. The Ag alloy may be an alloy such as silver (Ag), palladium (Pd) and copper (Cu). The reflective electrode 117 may be expressed as terms such as a second electrode, an opposing electrode and a cathode electrode.

The encapsulation layer 118 is formed on the reflective electrode 117. The encapsulation layer 118 serves to prevent or at least reduce oxygen or moisture from penetrating into the organic light-emitting layer 116 and the reflective electrode 117. The encapsulation layer 118 may be provided with a plurality of layers including at least one inorganic film and at least one organic film. The encapsulation layer 118 may further contain an absorbent material for absorbing moisture or oxygen in order to enhance the moisture-prevention effect. For example, the absorbent material may be a getter.

Meanwhile, as shown in FIG. 3, the encapsulation layer 118 may be arranged in the light-emission area EA and in the non-light emission area NEA. The encapsulation layer 118 may be arranged between the reflective electrode 117 and the opposing substrate 200.

Referring to FIGS. 3 and 4, in the display apparatus 100 according to one embodiment of the present disclosure, the first planarization layer 120 may further include a lower upper surface 122 and a lower bottom surface 123.

The lower upper surface 122 may be connected to one side of the lower sloped portion 121. For example, with reference to FIG. 4, the lower upper surface 122 may be connected to a right end (e.g., a first end) of the lower sloped portion 121. According to one example, the lower upper surface 122 may parallel to the upper surface 110a of the substrate 110. Accordingly, the lower upper surface 122 may be relatively flat.

The lower bottom surface 123 may be connected to the other side of the lower sloped portion 121. For example, with reference to FIG. 4, the lower bottom surface 123 may be connected to a left end (e.g., a second end) of the lower sloped portion 121. Therefore, the lower bottom surface 123 may be spaced apart from the lower upper surface 122. According to one example, the lower bottom surface 123 may parallel to the upper surface 110a of the substrate 110, thereby being provided flat.

As described above, the lower pattern portion can be formed by partially removing the first planarization layer 120 that partially overlaps the light-emission area EA. Accordingly, the lower bottom surface 123 can be positioned closer to the substrate 110 than the lower upper surface 122. In addition, the lower bottom surface 123 connected to the other side of the lower sloped portion 121 can overlap with the light-emission area EA.

Referring to FIG. 4, in the display apparatus 100 according to one embodiment of the present disclosure, the second planarization layer 130 may further include an upper top surface 132 and an upper bottom surface 133.

The upper top surface 132 may be connected to one side of the upper sloped portion 131. For example, based on FIG. 4, the upper top surface 132 may be connected to a left end (e.g., a first end) of the upper sloped portion 131. According to one example, the upper top surface 132 may be provided parallel to the upper surface 110a of the substrate 110. Accordingly, the upper top surface 132 may be relatively flat. As shown in FIG. 4, the pixel electrode 114 may be partially arranged on the upper top surface 132 of the second planarization layer 130.

The upper bottom surface 133 may be connected to the other side of the upper sloped portion 131. For example, based on FIG. 4, the upper bottom surface 133 may be connected to a right end (e.g., a second end) of the upper sloped portion 131. Therefore, the upper bottom surface 133 may be spaced apart from the upper top surface 132. According to one example, the upper bottom surface 133 may be provided parallel to the upper surface 110a of the substrate 110, and thus may be provided flat.

As described above, the upper pattern portion may be formed by partially removing the second planarization layer 130 between the plurality of subpixels SP. Accordingly, the upper pattern portion may be provided in the non-light emission area NEA, and the upper bottom surface 133 may be arranged closer to the substrate 110 than the upper top surface 132. Accordingly, the display apparatus 100 according to one embodiment of the present disclosure may have a structural feature in which a first separation distance D1 (shown in FIG. 3) between the upper top surface 132 and the lower bottom surface 123 is provided longer than a second separation distance D2 between the upper bottom surface 133 and the lower top surface 122.

As shown in FIG. 3, in a display apparatus 100 according to one embodiment of the present disclosure, light reflected by the sloped reflective portion 140 is refracted by each of the upper sloped portion 131 and the lower sloped portion 121 that are arranged to be inclined in different directions (e.g., acute angles and obtuse angles), so that it can be emitted toward the center of the light-emission area EA rather than the front direction.

Specifically, referring to FIG. 4, light emitted from the organic light-emitting layer 116 and reflected by the sloped reflective portion 140 may be first refracted by the upper sloped portion 131 and then incident on the lower sloped portion 121 at a first angle θ1 with respect to a normal line ML of the lower sloped portion 121. The light incident on the lower sloped portion 121 at the first angle θ1 may be refracted at a second angle θ2 by the lower sloped portion 121 and incident on the substrate 110 at a third angle θ3 with respect to the vertical direction of the upper surface 110a of the substrate 110. Here, the second angle θ2 may be an angle formed by a normal line ML of the lower sloped portion 121 and an optical path line of light refracted by the lower sloped portion 121. The third angle θ3 may be an angle formed by a virtual line perpendicular to the upper surface 110a of the substrate 110 and an optical path line of light refracted by the lower sloped portion 121 at the second angle θ2 and incident on the substrate 110. Light incident on the substrate 110 at the third angle θ3 can be refracted at a fourth angle θ4 at the boundary between the substrate 110 and the outside air (or air outside the substrate) and emitted to the outside of the substrate 110.

Therefore, the display apparatus 100 according to one embodiment of the present disclosure can have a viewing angle that is refracted in a direction other than the frontal direction, for example, in a direction toward a center of the light-emission area EA, so that the viewing angle can be improved.

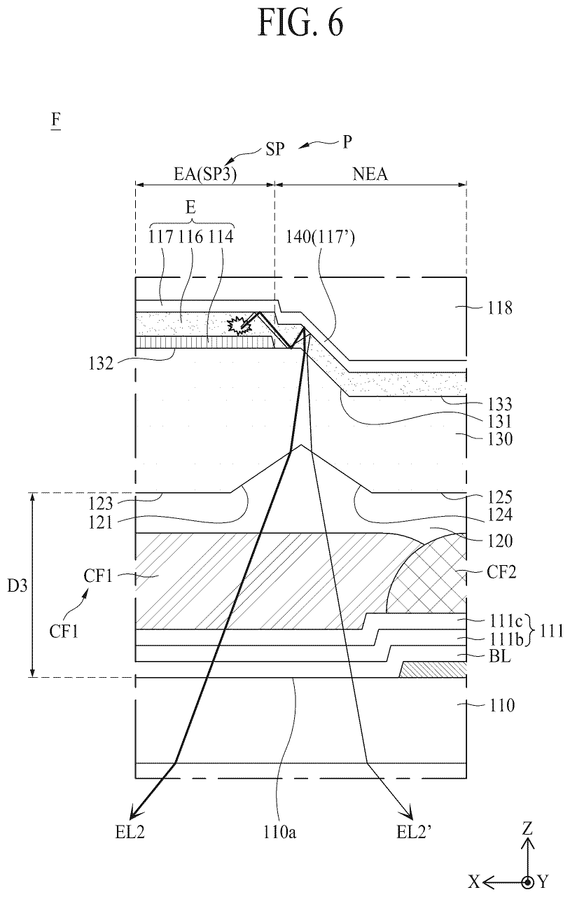

FIG. 6 is a schematic partial cross-sectional view of a display apparatus according to a second embodiment of the present disclosure.

Referring to FIG. 6, the display apparatus 100 according to the second embodiment of the present disclosure is the same as the display apparatus according to FIG. 1 described above, except that a structure of the first planarization layer 120 is changed. Therefore, the same drawing reference numerals are given to the same configurations, and only different configurations will be described below.

In the case of the display apparatus according to FIG. 1, it is provided to include the upper sloped portion 131 partially overlapping the sloped reflective portion 140, and the lower sloped portion 121 positioned closer to the substrate 110 than the upper sloped portion 131. Here, each of the upper sloped portion 131 and the lower sloped portion 121 may be positioned to be inclined in different directions. Accordingly, in the case of the display apparatus according to FIG. 1, the light reflected by the sloped reflective portion 140 is refracted in one direction toward the center of the light-emission area EA (or a center of a light-emission area EA of an emitting subpixel SP) rather than the front direction by the upper sloped portion 131 and the lower sloped portion 121 which are arranged to be inclined in different directions, so that the viewing angle on one side based on the front direction can be improved.

Meanwhile, in the case of the display apparatus according to FIG. 1, the first planarization layer 120 may be provided to include a lower sloped portion 121, a lower upper surface 122, and a lower bottom surface 123. And, in the case of the display apparatus according to FIG. 1, the lower pattern portion may have a structural feature in which the first planarization layer 120 partially overlapping the light-emission area EA is partially removed and formed, so that the lower sloped portion 121 and the lower bottom surface 123 partially overlap the light-emission area EA and the lower upper surface 122 overlap the non-light emission area NEA.

In contrast, in the case of the display apparatus according to FIG. 6, the first planarization layer 120 may include a lower sloped portion 121, a lower bottom surface 123, an outer sloped portion 124, and an outer bottom surface 125.

The lower bottom surface 123 can be connected to one side of the lower sloped portion 121. For example, with reference to FIG. 6, the lower bottom surface 123 can be connected to a left end of the lower sloped portion 121.

The outer sloped portion 124 may be connected to the other side of the lower sloped portion 121. For example, with reference to FIG. 6, the outer sloped portion 124 may be connected to a right end of the lower sloped portion 121. Accordingly, the outer sloped portion 124 may be spaced apart from the lower bottom surface 123. According to one example, the outer sloped portion 124 may be formed to be inclined in the same direction as the upper sloped portion 131. The lower sloped portion 121 and the outer sloped portion 124 thereby form a peak in the cross-section view of the display apparatus.

The outer bottom surface 125 may be connected to the outer sloped portion 124. For example, based on FIG. 6, the outer bottom surface 125 may be connected to a right end of the outer sloped portion 124. Therefore, the outer bottom surface 125 may be spaced apart from the lower sloped portion 121. According to one example, the outer bottom surface 125 may be provided parallel to the upper surface 110a of the substrate 110, and thus may be provided flat.

In the display apparatus 100 according to the second embodiment of the present disclosure, the outer sloped portion 124 and the outer bottom surface 125 may be formed by partially removing the first planarization layer 120 that partially overlaps the non-light emission area NEA. Accordingly, the substrate 110 may include a pattern portion (or an outer pattern portion) that is formed concavely and partially overlaps the non-light emission area NEA between the plurality of subpixels SP. According to one example, a width of the pattern portion (or the outer pattern portion) may be formed to become narrower in the direction from the opposing substrate 200 toward the substrate 110.

The outer sloped portion 124 may be an inclined surface of the pattern portion (or the outer pattern portion) formed concavely in the non-light emission area NEA, and the outer bottom surface 125 may be a flat surface of the pattern portion (or the outer pattern portion) provided flatly in the non-light emission area NEA.

Therefore, as shown in FIG. 6, the display apparatus 100 according to the second embodiment of the present disclosure may have the outer sloped portion 124 partially overlapped with the upper sloped portion 131. Therefore, in the display apparatus 100 according to the second embodiment of the present disclosure, some of the light reflected by the sloped reflective portion 140 can be refracted in a direction (e.g., toward the left side with reference to FIG. 6) toward the center of the light-emission area EA rather than the front direction by the upper sloped portion 131 and the lower sloped portion 121, so that the viewing angle can be improved, and some of the light reflected by the sloped reflective portion 140 can be refracted in a direction (e.g., toward the right side with reference to FIG. 6) toward the adjacent subpixel SP rather than the front direction by the upper sloped portion 131 and the outer sloped portion 124, so that the viewing angle can be improved.

As a result, the display apparatus 100 according to the second embodiment of the present disclosure has light reflected by the sloped reflective portion 140 refracted in both directions toward the center of the light-emission area EA and the adjacent subpixel SP rather than the front direction through the lower sloped portion 121 and the outer sloped portion 124, so that the viewing angle can be improved in both directions based on the front direction.

Hereinafter, light refracted toward the center of the light-emission area EA in the display apparatus 100 according to the second embodiment of the present disclosure is defined as second refracted light EL2, and light refracted toward an adjacent subpixel SP is defined as second' refracted light EL2′.

Meanwhile, as described above, the outer pattern portion can be formed by partially removing the first planarization layer 120 that partially overlaps the non-light emission area NEA. This outer pattern portion can be formed together with the formation of the lower pattern portion. Accordingly, the lower pattern portion can partially overlap the light emission area EA, and the outer pattern portion can overlap the non-light emission area NEA. The display apparatus 100 according to the second embodiment of the present disclosure may have a structural feature in which the outer pattern portion is formed together with the lower pattern portion, so that the lower bottom surface 123 and the outer bottom surface 125 are provided with the same distance from the substrate 110. For example, each of the lower bottom surface 123 and the outer bottom surface 125 may be provided with a third separation distance D3 from the upper surface 110a of the substrate 110.

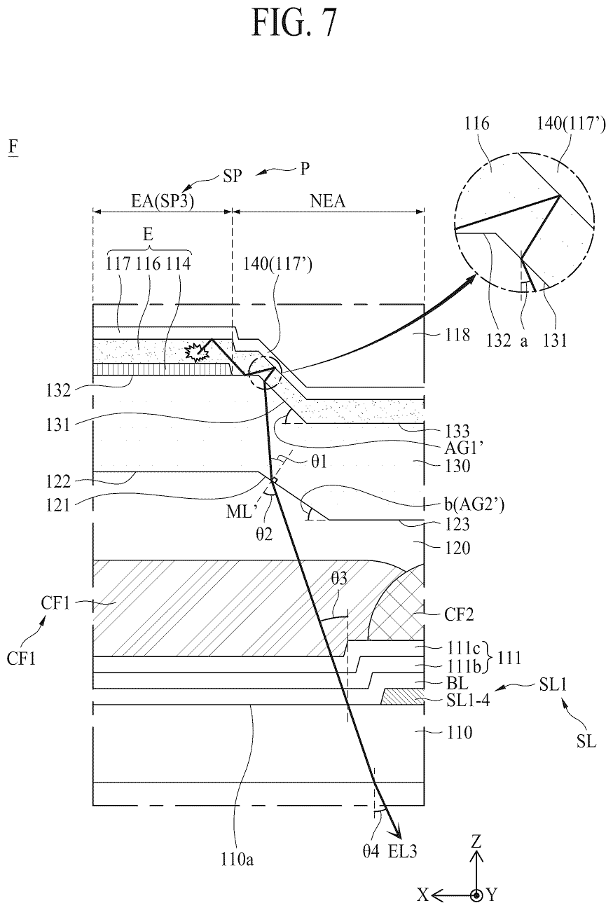

FIG. 7 is a schematic partial cross-sectional view of a display apparatus according to a third embodiment of the present disclosure.

Referring to FIG. 7, the display apparatus 100 according to the third embodiment of the present disclosure is the same as the display apparatus according to FIG. 1 described above, except that a structure of the first planarization layer 120 is changed. Therefore, the same drawing reference numerals are given to the same configurations, and only different configurations will be described below.

In the case of the display apparatus according to FIG. 1, the upper sloped portion 131 and the lower sloped portion 121 can be arranged to be inclined in different directions. Accordingly, in the case of the display apparatus according to FIG. 1, the light reflected by the sloped reflective portion 140 is refracted in one direction toward the center of the light-emission area EA (or a center of a light-emission area EA of an emitting subpixel SP) rather than the front direction by the upper sloped portion 131 and the lower sloped portion 121 which are arranged to be inclined in different directions, so that the viewing angle on one side based on the front direction can be improved.

In addition, in the case of the display apparatus according to FIG. 1, the lower pattern portion may have a structural feature in which the first planarization layer 120 partially overlapping the light-emission area EA is partially removed and formed, so that the lower sloped portion 121 and the lower bottom surface 123 partially overlap the light-emission area EA and the lower upper surface 122 overlap the non-light-emission area NEA.

In contrast, in the case of the display apparatus according to FIG. 7, the first planarization layer 120 may be provided to include a lower sloped portion 121, a lower upper surface 122, and a lower bottom surface 123. Here, the lower upper surface 122 may be connected to one side of the lower sloped portion 121. For example, with reference to FIG. 7, the lower upper surface 122 may be connected to a left end of the lower sloped portion 121. According to one example, the lower upper surface 122 may be provided parallel to the upper surface 110a of the substrate 110. Accordingly, the lower upper surface 122 may be provided flat.

The lower bottom surface 123 may be connected to the other side of the lower sloped portion 121. For example, based on FIG. 7, the lower bottom surface 123 may be connected to a right end of the lower sloped portion 121. Therefore, the lower bottom surface 123 may be spaced apart from the lower upper surface 122. According to one example, the lower bottom surface 123 may be provided parallel to the upper surface 110a of the substrate 110, thereby being provided flat.

In the display apparatus according to FIG. 7, the lower pattern portion may be formed by partially removing the first planarization layer 120 overlapping the non-light emission area NEA. Accordingly, the display apparatus according to FIG. 7 may be provided so that the lower sloped portion 121 does not overlap the light emission area EA. For example, in the case of the display apparatus according to FIG. 7, the lower sloped portion 121 may be provided so as to partially overlap each of the upper sloped portion 131 and the sloped reflective portion 140 provided in the non-light emission area NEA.

Meanwhile, the display apparatus according to FIG. 7 is formed by partially removing the first planarization layer 120 overlapping the lower pattern portion with the non-light emission area NEA, so that each of the lower sloped portion 121 and the upper sloped portion 131 can be arranged at an acute angle with respect to the upper surface 110a of the substrate 110. For example, as shown in FIG. 7, the upper sloped portion 131 can be arranged at an acute angle (AG1′) with respect to the upper surface 110a of the substrate 110. And, the lower sloped portion 121 may be arranged at an acute angle (AG2′ or b) with respect to the upper surface 110a of the substrate 110. Therefore, the display apparatus according to FIG. 7 may be formed such that the upper sloped portion 131 and the lower sloped portion 121 are inclined in the same direction. Here, the same direction does not mean the same angle. The upper sloped portion 131 and the lower sloped portion 121 may be arranged such that they are inclined in a direction toward the substrate 110 (or in a direction closer to the substrate 110) as they go to a right with respect to FIG. 7.

Therefore, as shown in FIG. 7, the display apparatus 100 according to the third embodiment of the present disclosure refracts light reflected by the sloped reflective portion 140 in one direction toward an adjacent subpixel rather than the front direction by the upper sloped portion 131 and the lower sloped portion 121 which are arranged to be inclined in the same direction, so that a viewing angle on one side based on the front direction can be improved. Here, the one-side direction may mean a right direction based on FIG. 7. The right direction may be a direction (or an outward direction) from an emitting subpixel SP toward a non-emitting subpixel SP.

Hereinafter, light refracted toward an adjacent subpixel SP (or a non-emitting subpixel SP) in the display apparatus 100 according to the third embodiment of the present disclosure is defined as third refracted light EL3.

Meanwhile, in the case of the display apparatus according to FIG. 7, the first planarization layer 120 that overlaps the lower pattern portion with the non-light emission area NEA is partially removed and formed, so that the lower sloped portion 121 and the lower bottom surface 123 overlap the non-light emission area NEA and the lower upper surface 122 partially overlaps the light emission area EA.

In addition, in the case of the display apparatus according to FIG. 7, the lower pattern portion may have a structural feature in which the first planarization layer 120 overlapping the non-light emission area NEA is partially removed and formed, so that the lower bottom surface 123 provided in the non-light emission area NEA is positioned closer to the substrate 110 than the lower upper surface 122 partially overlapping the light emission area EA.

Referring to FIG. 7, light emitted from the organic light-emitting layer 116 and reflected by the sloped reflective portion 140 can be emitted to an outside of the substrate 110 through the following light path.

First, light reflected by the sloped reflective portion 140 among the light emitted from the organic light-emitting layer 116 may be incident on the upper sloped portion 131. The light incident on the upper sloped portion 131 may be refracted at an angle a by the upper sloped portion 131 and then incident on the lower sloped portion 121. Here, the angle α may be from 0° to 27° with respect to the direction perpendicular to the upper surface 110a of the substrate 110, but is not necessarily limited thereto.

Next, light refracted at an angle a by the upper sloped portion 131 can be incident on the lower sloped portion 121 at a first angle θ1 with respect to a normal line ML′ of the lower sloped portion 121. Light incident on the lower sloped portion 121 at the first angle θ1 can be refracted at a second angle θ2 by the lower sloped portion 121. Here, the second angle θ2 can be an angle formed by the normal line ML′ of the lower sloped portion 121 and the optical path line of light refracted by the lower sloped portion 121.

Next, light refracted at the second angle θ2 by the lower sloped portion 121 can be incident on the substrate 110 at a third angle θ3 with respect to a vertical direction of the upper surface 110a of the substrate 110.

Next, light incident on the substrate 110 at the third angle θ3 can be refracted at a fourth angle θ4 at the boundary between the substrate 110 and an outside air (or air outside the substrate 110) and emitted to the outside of the substrate 110.

Therefore, the display apparatus 100 according to the third embodiment of the present disclosure can improve a viewing angle because the viewing angle can be refracted in a direction other than the frontal direction, for example, in a direction (or in an outward direction) toward an adjacent subpixel (or a non-emitting subpixel).

Meanwhile, in the display apparatus 100 according to the third embodiment of the present disclosure, the second angle θ2 of light refracted by the lower sloped portion 121 may be provided to satisfy the following mathematical expression (or mathematical expression 1).

$$sin ( θ 2 ) = n 1 / n 2 \times sin ( θ1 )$$

A n1 is a refractive index of the second planarization layer 130. A n2 is a refractive index of the first planarization layer 130. As described above, the first angle θ1 may be an angle at which light refracted by the upper sloped portion 131 is incident on the lower sloped portion 121. For example, the first angle θ1 may be an angle formed by a normal line ML′ of the lower sloped portion 121 and an optical path line of light refracted by the upper sloped portion 131.

In addition, in the display apparatus 100 according to the third embodiment of the present disclosure, the fourth angle θ4 of light refracted at the boundary between the substrate 110 and the outside air (or air outside the substrate 110) may be provided to satisfy the following mathematical expression (or mathematical expression 2).

$$sin ( θ4 ) = n 3 / n 4 \times sin ( θ 3 )$$

A n3 is a refractive index of the substrate 110. A n4 is a refractive index of the outside air. For example, the refractive index of the outside air may be 1. As described above, the third angle θ3 may be an angle at which light refracted by the lower sloped portion 121 is incident on the substrate 110. For example, the third angle θ3 may be an angle at which light refracted by the lower sloped portion 121 is incident relative to a direction perpendicular to the upper surface 110a of the substrate 110.

The display apparatus 100 according to the third embodiment of the present disclosure is provided such that the second angle θ2 of light refracted by the lower sloped portion 121 and the fourth angle θ4 of light refracted at a boundary between the substrate 110 and the outside air (or air outside the substrate 110) satisfy the mathematical expressions 1 and 2 above, so that among the light emitted from the organic light-emitting layer 116, the light reflected by the sloped reflective portion 140 is refracted in one direction (or in the outward direction) toward an adjacent subpixel rather than in the front direction by the lower sloped portion 121 and the substrate 110, and thus the viewing angle in one direction (or in the outward direction) with respect to the front direction can be improved.

The following [Table 1] is a simulation results of the first angle θ1, the second angle θ2, the third angle θ3, and the fourth angle θ4 according to the angle a, in a display apparatus 100 according to the third embodiment of the present disclosure, when the refractive index of the first planarization layer 120 is 1.45, the refractive index of the second planarization layer 130 is 1.64, and the b angle is 60°. The angle b may be an angle formed by the lower sloped portion 121 with respect to the upper surface 110a of the substrate 110. The first angle θ1 may be an incident angle of light incident on the lower sloped portion 121. The second angle θ2 may be an exit angle of light refracted by the lower sloped portion 121. The third angle θ3 may be an incident angle of light incident on the substrate 110. The fourth angle θ4 may be an exit angle of light refracted at the boundary between the substrate 110 and the outside air.

TABLE 1

| a | θ1 | θ2 | θ3 | θ4 |
|---|---|---|---|---|
| 0 | 30 | 34.4 | 4.4 | 6.4 |
| 5 | 35 | 40.4 | 10.4 | 15.2 |
| 10 | 40 | 46.6 | 16.6 | 24.5 |
| 15 | 45 | 53.1 | 23.1 | 34.7 |
| 20 | 50 | 60.0 | 30.0 | 46.6 |
| 25 | 55 | 67.9 | 37.9 | 62.9 |
| 27 | 57 | 71.5 | 41.5 | 74.1 |

As shown in [Table 1] above, as the angle a increases from 0° to 27°, the first angle θ1 increases from 30° to 57°, the second angle θ2 increases from 34.4° to 71.5°, the third angle θ3 increases from 4.4° to 41.5°, and the fourth angle θ4 increases from 6.4° to 74.1°.

Therefore, according to the third embodiment of the present specification, the display apparatus 100 can be seen to improve a viewing angle of light (or third refracted light EL3) finally emitted from the substrate 110 from 6.4° to 74.1° when the angle a of light refracted by the upper sloped portion 131 increases from 0° to 27°.

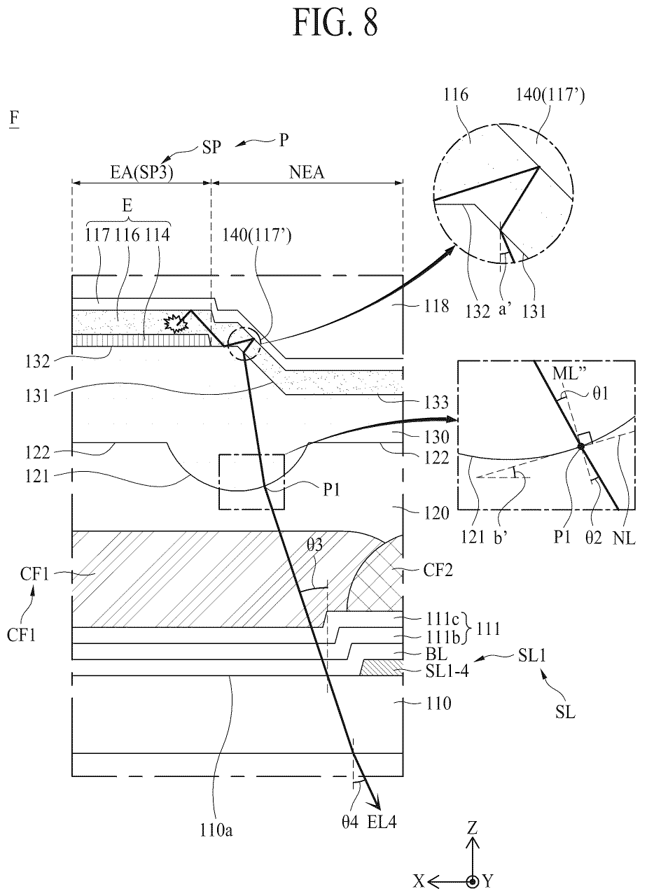

FIG. 8 is a schematic partial cross-sectional view of a display apparatus according to a fourth embodiment of the present disclosure.

Referring to FIG. 8, the display apparatus 100 according to the fourth embodiment of the present disclosure is the same as the display apparatus according to FIG. 1 described above, except that a shape of the first planarization layer 120 (or lower sloped portion 121) is changed. Therefore, the same drawing reference numerals are given to the same configurations, and only different configurations will be described below.

In the case of the display apparatus according to FIG. 1, the lower sloped portion 121 is provided as a straight inclined surface. Accordingly, in the case of the display apparatus according to FIG. 1, the light reflected by the sloped reflective portion 140 is refracted in one direction (or inward direction) toward the center of the light-emission area EA (or the center of the light-emission area EA of the light-emitting subpixel SP) rather than the front direction by the upper sloped portion 131 and the lower sloped portion 121 which are arranged to be inclined in different directions, so that a viewing angle in one direction (or inward direction) based on the front direction can be improved.

In addition, in the case of the display apparatus according to FIG. 1, the lower pattern portion may have a structural feature in which the first planarization layer 120 partially overlapping the light-emission area EA is partially removed and formed, so that the lower sloped portion 121 and the lower bottom surface 123 partially overlap the light-emission area EA and the lower upper surface 122 overlap the non-light-emission area NEA.

In contrast, in the case of the display apparatus according to FIG. 8, the lower sloped portion 121 may be provided in a hemispherical shape. For example, as shown in FIG. 8, the lower sloped portion 121 may be formed by removing the first planarization layer 120 partially overlapping each of the light-emission area EA and the non-light-emission area NEA in a hemispherical shape. Accordingly, in the case of the display apparatus according to FIG. 8, the lower sloped portion 121 may be provided so as to overlap the sloped reflective portion 140. For example, based on FIG. 8, a left part of the lower sloped portion 121 may partially overlap the pixel electrode 114, and a right part of the lower sloped portion 121 may partially overlap the sloped reflective portion 140. As shown in FIG. 8, the upper sloped portion 131 is positioned between the lower sloped portion 121 and the sloped reflective portion 140, and thus may overlap the lower sloped portion 121 having a hemispherical shape.

Meanwhile, in the case of the display apparatus according to FIG. 8, since the lower sloped portion 121 is formed by removing the first planarization layer 120 partially overlapping each of the light-emission area EA and the non-light-emission area NEA in a hemispherical shape, the lower upper surface 122 may be connected to both sides of the lower sloped portion 121 and the lower bottom surface may be omitted, thereby having a structural feature. As shown in FIG. 8, the central portion of the lower sloped portion 121 having a hemispherical shape may be arranged closer to the substrate 110 than the lower upper surface 122.

Therefore, as shown in FIG. 8, the display apparatus 100 according to the fourth embodiment of the present disclosure refracts light reflected by the sloped reflective portion 140 toward an adjacent subpixel in one direction (or outward direction) rather than the front direction by the upper sloped portion 131 having a straight shape and the lower sloped portion 121 having a hemispherical shape, so that a viewing angle in one direction (or outward direction) based on the front direction can be improved. Here, the one direction (or outward direction) may mean a right direction based on FIG. 8. The right direction may be a direction from an emitting subpixel SP toward a non-emitting subpixel SP.

Hereinafter, in the display apparatus 100 according to the fourth embodiment of the present disclosure, light refracted toward an adjacent subpixel SP (or a non-emitting subpixel SP) is defined as fourth refracted light EL4. As shown in FIG. 8, a first subline SL1-4 can be arranged so as not to interfere with the fourth refracted light EL4.

Referring to FIG. 8, light emitted from the organic light-emitting layer 116 and reflected by the sloped reflective portion 140 can be emitted to an outside of the substrate 110 through the following light path.

First, light reflected by the sloped reflective portion 140 among the light emitted from the organic light-emitting layer 116 may be incident on the upper sloped portion 131. The light incident on the upper sloped portion 131 may be refracted primarily at an angle a′ by the upper sloped portion 131 and then incident on the lower sloped portion 121. Here, the angle a′ may be from 30° to 42°, but is not necessarily limited thereto.

Next, the light refracted at an angle a′ by the upper sloped portion 131 can be incident on the lower sloped portion 121 at a first angle θ1 with respect to a normal line ML″ of the lower sloped portion 121. The normal line ML″ of the lower sloped portion 121 can be a normal line perpendicular to a normal line NL of a point (e.g., a first point P1 of the lower sloped portion 121) at which the light refracted at an angle a′ by the upper sloped portion 131 is incident. Light incident on the lower sloped portion 121 at the first angle θ1 can be refracted by the lower sloped portion 121 at a second angle θ2. Here, the second angle θ2 can be an angle formed by a normal line ML″ of the lower sloped portion 121 and an optical path line of light refracted by the lower sloped portion 121.

Next, light refracted at the second angle θ2 by the lower sloped portion 121 can be incident on the substrate 110 at a third angle θ3 with respect to a vertical direction of the upper surface 110a of the substrate 110.

Next, light incident on the substrate 110 at the third angle θ3 can be refracted at a fourth angle θ4 at a boundary between the substrate 110 and the outside air (or air outside the substrate 110) and emitted to an outside of the substrate 110.

Therefore, the display apparatus 100 according to the fourth embodiment of the present disclosure can improve a viewing angle because the viewing angle can be refracted in a direction other than the frontal direction, for example, in a direction (or in an outward direction) toward an adjacent subpixel (or a non-emitting subpixel).

The following [Table 2] shows a simulation results of the first angle θ1, the second angle θ2, the third angle θ3, and the fourth angle θ4 according to the angle a in the display apparatus 100 according to the fourth embodiment of the present disclosure, when a refractive index of the first planarization layer 120 is 1.45, a refractive index of the second planarization layer 130 is 1.64, and a b angle is 60°. The angle b may be an angle formed by a normal line NL of the first point P1 with respect to the upper surface 110a of the substrate 110. The first angle θ1 may be an incident angle of light incident on the lower sloped portion 121. The second angle θ2 may be an exit angle of light refracted by the lower sloped portion 121. The third angle θ3 may be an incident angle of light incident on the substrate 110. The fourth angle θ4 may be an exit angle of light refracted at a boundary between the substrate 110 and the outside.

TABLE 2

| a | θ1 | θ2 | θ3 | θ4 |
|---|---|---|---|---|
| 30 | 0 | 0 | 30 | 46.5 |
| 35 | 5 | 5.7 | 35.7 | 57.7 |
| 40 | 10 | 11.3 | 41.3 | 73.2 |
| 42 | 12 | 13.6 | 43.6 | 89.5 |

As shown in [Table 2] above, as the angle a increases from 30° to 42°, the first angle θ1 increases from 0° to 12°, the second angle θ2 increases from 0° to 13.6°, the third angle θ3 increases from 30° to 43.6°, and the fourth angle θ4 increases from 46.5° to 89.5°.

Therefore, it can be seen that when the angle a of light refracted by the upper sloped portion 131 according to the fourth embodiment of the present disclosure increases from 30° to 42°, a viewing angle of light (or fourth refracted light EL4) finally emitted from the substrate 110 is improved from 46.5° to 89.5°.

Embodiments of the present disclosure have been described in more detail with reference to the accompanying drawings, but the present disclosure is not necessarily limited to these embodiments and may be implemented in various modifications without departing from the technical ideas of the present disclosure. Accordingly, the embodiments disclosed herein are intended to illustrate and not to limit the technical ideas of the present disclosure, and the scope of the technical ideas of the present disclosure is not limited by these embodiments. Therefore, the embodiments described above are exemplary in all respects and should be understood as non-limiting. The scope of protection of this disclosure shall be construed by the claims, and all technical ideas within the scope of the claims shall be construed to be included within the scope of the claims.

The present disclosure is provided to include an upper sloped portion partially overlapping with a sloped reflective portion and a lower sloped portion positioned closer to the substrate than the upper sloped portion, so that light reflected by the sloped reflective portion can be refracted in a direction other than the front direction by each of the upper sloped portion and the lower sloped portion, thereby improving the viewing angle.

Furthermore, the display apparatus according to the present disclosure is provided with a sloped reflective portion that is inclinedly arranged in a non-light emission area, so that light directed toward an adjacent subpixel can be reflected by the sloped reflective portion and emitted to an outside of the substrate, thereby improving light extraction efficiency.

Furthermore, since the display apparatus according to the present disclosure can achieve light extraction even by a sloped reflective portion, it can have the same luminous efficiency or improve luminous efficiency more than that of a display apparatus without a sloped reflective portion even with low power consumption, so that the overall power consumption can be reduced.

In one embodiment, a display apparatus comprises: a substrate having a plurality of subpixels; a first planarization layer on the substrate; a second planarization layer on the first planarization layer, the second planarization layer having a refractive index that is different from a refractive index of the first planarization layer; and a sloped reflective portion on the second planarization layer, the sloped reflective portion inclined with respect to the substrate in a non-light emission area that is between the plurality of subpixels, wherein the second planarization layer includes an upper sloped portion that partially overlaps the sloped reflective portion and is arranged obliquely with respect to the substrate, wherein the first planarization layer includes a lower sloped portion that is closer to the substrate than the upper sloped portion and is arranged obliquely with respect to the substrate.

In one embodiment, the refractive index of the second planarization layer is greater than the refractive index of the first planarization layer.

In one embodiment, each of the plurality of subpixels includes a light-emission area that is adjacent to the non-light-emission area, and the upper sloped portion is non-overlapping with the light-emission area.

In one embodiment, each of the upper sloped portion and the lower sloped portion refracts light reflected by the sloped reflective portion that is emitted from the light-emission area.

In one embodiment, each of the plurality of subpixels comprises a pixel electrode on the second planarization layer, an organic light-emitting layer on the pixel electrode, and a reflective electrode on the organic light-emitting layer, and the sloped reflective portion is a part of the reflective electrode.

In one embodiment, the lower sloped portion is arranged at an obtuse angle with respect to an upper surface of the substrate and the upper sloped portion is arranged at an acute angle with respect to the upper surface of the substrate.

In one embodiment, the lower sloped portion is partially overlapped with the light-emission area.

In one embodiment, the first planarization layer further includes a lower upper surface connected to a first side of the lower sloped portion and a lower bottom surface spaced from the lower upper surface, the lower bottom surface being connected to a second side of the lower sloped portion, wherein the lower bottom surface is closer to the substrate than the lower upper surface.

In one embodiment, the lower bottom surface overlaps the light-emission area.

In one embodiment, the second planarization layer further includes an upper top surface connected to a first side of the upper sloped portion and an upper bottom surface spaced apart from the upper top surface, the upper bottom surface being connected to a second side of the upper sloped portion, wherein a first separation distance between the upper top surface and the lower bottom surface is greater than a second separation distance between the upper bottom surface and the lower upper surface.

In one embodiment, the first planarization layer comprises a lower bottom surface connected to a first side of the lower sloped portion, an outer sloped portion spaced from the lower bottom surface and connected to a second side of the lower sloped portion, and an outer bottom surface spaced from the lower sloped portion and connected to the outer sloped portion.

In one embodiment, the outer sloped portion partially overlaps the upper sloped portion of the second planarization layer.

In one embodiment, a distance between the lower bottom surface and the substrate is the same as a distance between the outer bottom surface and the substrate.

In one embodiment, each of the lower sloped portion and the upper sloped portion has an acute angle with respect to an upper surface of the substrate.

In one embodiment, the lower sloped portion partially overlaps with the upper sloped portion of the second planarization layer and the sloped reflective portion.

In one embodiment, the lower sloped portion is non-overlapping with the light-emission area.

In one embodiment, the first planarization layer further includes a lower upper surface connected to a first side of the lower sloped portion and a lower bottom surface spaced from the lower upper surface and connected to a second side of the lower sloped portion, wherein the lower bottom surface overlaps the non-light-emission area.

In one embodiment, light reflected by the sloped reflective portion and incident on the upper sloped portion is incident on the lower sloped portion at a first angle θ₁ with respect to a normal line of the lower sloped portion, and light incident on the lower sloped portion at the first angle θ₁ is refracted at a second angle θ₂ by the lower sloped portion, and the second angle θ₂ is provided to satisfy a mathematical expression below, wherein n₁ is a refractive index of the second planarization layer and n₂ is a refractive index of the first planarization layer.

In one embodiment, the light refracted at the second angle θ₂ is incident on the substrate at a third angle θ₃ with respect to a vertical direction of the substrate, the light incident on the substrate at the third angle θ₃ is refracted at a fourth angle θ₄ at a boundary between the substrate and an outside, and the fourth angle θ₄ is provided to satisfy a mathematical expression below, wherein n₃ is a refractive index of the substrate and n₄ is a refractive index of an outside air.

In one embodiment, the lower sloped portion has a hemispherical shape.

The effects that may be obtained from the present disclosure are not limited to those mentioned above, and other effects not mentioned will be apparent to one having ordinary skill in the art from the following description.

What is claimed is:

1. A display apparatus comprising:
a substrate having a plurality of subpixels;
a first planarization layer on the substrate;
a second planarization layer on the first planarization layer, the second planarization layer having a refractive index that is different from a refractive index of the first planarization layer; and
a sloped reflective portion on the second planarization layer, the sloped reflective portion inclined with respect to the substrate in a non-light emission area that is between the plurality of subpixels,
wherein the second planarization layer includes an upper sloped portion that partially overlaps the sloped reflective portion and is arranged obliquely with respect to the substrate,
wherein the first planarization layer includes a lower sloped portion that is closer to the substrate than the upper sloped portion and is arranged obliquely with respect to the substrate.

2. The display apparatus of claim 1, wherein the refractive index of the second planarization layer is greater than the refractive index of the first planarization layer.

3. The display apparatus of claim 1, wherein each of the plurality of subpixels includes a light emission area that is adjacent to the non-light emission area, and the upper sloped portion is non-overlapping with the light emission area.

4. The display apparatus of claim 3, wherein each of the upper sloped portion and the lower sloped portion refract light reflected by the sloped reflective portion that is emitted from the light emission area.

5. The display apparatus of claim 1, wherein each of the plurality of subpixels comprises:
a pixel electrode on the second planarization layer;
an organic light-emitting layer on the pixel electrode; and
a reflective electrode on the organic light-emitting layer,
wherein the sloped reflective portion is a part of the reflective electrode.

6. The display apparatus of claim 1, wherein the lower sloped portion is arranged at an obtuse angle with respect to an upper surface of the substrate and the upper sloped portion is arranged at an acute angle with respect to the upper surface of the substrate.

7. The display apparatus of claim 3, wherein the lower sloped portion is partially overlapped with the light emission area.

8. The display apparatus of claim 3, wherein the first planarization layer further includes:
a lower upper surface connected to a first side of the lower sloped portion; and
a lower bottom surface spaced from the lower upper surface, the lower bottom surface connected to a second side of the lower sloped portion,
wherein the lower bottom surface is closer to the substrate than the lower upper surface.

9. The display apparatus of claim 8, wherein the lower bottom surface overlaps the light emission area.

10. The display apparatus of claim 8, wherein the second planarization layer further includes:
an upper top surface connected to a first side of the upper sloped portion; and
an upper bottom surface spaced apart from the upper top surface, the upper bottom surface connected to a second side of the upper sloped portion,
wherein a first separation distance between the upper top surface and the lower bottom surface is greater than a second separation distance between the upper bottom surface and the lower upper surface.

11. The display apparatus of claim 3, wherein the first planarization layer comprises:
a lower bottom surface connected to a first side of the lower sloped portion;
an outer sloped portion spaced from the lower bottom surface, the outer sloped portion connected to a second side of the lower sloped portion; and
an outer bottom surface spaced from the lower sloped portion, the outer bottom surface connected to the outer sloped portion.

12. The display apparatus of claim 11, wherein the outer sloped portion partially overlaps the upper sloped portion of the second planarization layer.

13. The display apparatus of claim 11, wherein a distance between the lower bottom surface and the substrate is a same as a distance between the outer bottom surface and the substrate.

14. The display apparatus of claim 4, wherein each of the lower sloped portion and the upper sloped portion has an acute angle with respect to an upper surface of the substrate.

15. The display apparatus of claim 14, wherein the lower sloped portion partially overlaps with the upper sloped portion of the second planarization layer and the sloped reflective portion.

16. The display apparatus of claim 14, wherein the lower sloped portion is non-overlapping with the light emission area.

17. The display apparatus of claim 14, wherein the first planarization layer further includes:
a lower upper surface connected to a first side of the lower sloped portion; and
a lower bottom surface spaced from the lower upper surface and connected to a second side of the lower sloped portion,
wherein the lower bottom surface overlaps the non-light emission area.

18. The display apparatus of claim 14, wherein light reflected by the sloped reflective portion and incident on the upper sloped portion is incident on the lower sloped portion at a first angle θ1 with respect to a normal line of the lower sloped portion, and light incident on the lower sloped portion at the first angle θ1 is refracted at a second angle θ2 by the lower sloped portion, and the second angle θ2 is provided to satisfy a mathematical expression below,
$$sin ( θ2 ) = n 1 / n 2 \times sin ( θ1 )$$
wherein a n1 is a refractive index of the second planarization layer, and a n2 is a refractive index of the first planarization layer.

19. The display apparatus of claim 18, wherein the light refracted at the second angle θ2 is incident on the substrate at a third angle θ3 with respect to a vertical direction of the substrate, the light incident on the substrate at the third angle θ3 is refracted at a fourth angle θ4 at a boundary between the substrate and an outside, and the fourth angle θ4 is provided to satisfy a mathematical expression below,
$$sin ( θ4 ) = n 3 / n 4 \times sin ( θ 3 )$$
wherein a n3 is a refractive index of the substrate, and a n4 is a refractive index of an outside air.

20. The display apparatus of claim 1, wherein the lower sloped portion has a hemispherical shape.
